(19) United States
(12) Patent Application Publication
(10) Pub. No.: US 2004/0219438 A1
(43) Pub. Date: Nov. 4, 2004

(54) Photomask structure and method of reducing lens aberration and pattern displacement

(75) Inventor: Yuan-Hsun Wu, Taoyuan (TW)

Correspondence Address: QUINTERO LAW OFFICE, 1617 BROADWAY, 3RD FLOOR, SANTA MONICA, CA, 90404, US

(73) Assignee: Nanya Technology Corporation

(21) Appl. No.: 10/657,789

(22) Filed: Sep. 8, 2003

(30) Foreign Application Priority Data
May 1, 2003 (TW) 92112009

(51) Int. Cl. G03F 9/00; G03C 5/00

(52) U.S. Cl. 430/5; 430/322; 430/394

(57) ABSTRACT

A photomask structure for reducing lens aberration and pattern displacement and method thereof. The photomask consists of a transparent substrate and a light-shielding layer, with the light-shielding layer including an array pattern area and a plurality of assist patterns disposed therein. The distance between the assist pattern and its upper and lower array patterns is equal, and the length of the assist pattern is equal to the width of the array pattern. The method of reducing lens aberration and pattern displacement includes providing a substrate covered by a photoresist layer, forming patterns on the photoresist layer by a photomask, and etching an array trench area in the substrate using a patterned photoresist as a mask. According to the present invention, the uniformity of critical dimension between array patterns is improved and pattern displacement is reduced significantly.

### BACKGROUND OF THE INVENTION

1. Field of the Invention

The present invention relates to a photomask structure, and more specifically to a photomask structure for reducing lens aberration and pattern displacement and method thereof.

2. Description of the Related Art

In semiconductor fabrication, lithography is accomplished by subjecting a wafer to step-by-step (or scan-by-scan) exposure. Before performing lithography, several parameters, such as photoresist coating thickness, baking/cooling temperature, and time, developing mechanism and time, exposure dose, best focus offset and numerical aperture (NA), must be tuned and optimized. Next, etching is conducted to transfer the photoresist pattern to the underlying layer. Additionally, before etching, several parameters, such as gas ratio, flow rate, bias pressure power, etching temperature and mode, must be tuned. By means of tuning lithography and etching parameters, the predetermined critical dimension (CD) can thus be achieved.

When after-etching-inspection (AEI) is performed, however, it is always found that there exists CD bias between array patterns, which may result in a fatal failure such as a contact hole “open” in the wafer acceptance test (WAT). These failures severely affect yield.

CD bias between array patterns mainly results from lens aberration, such as spherical lens aberration, astigmatism, coma lens aberration, field curvature, and distortion. Innate defects in lens material, diffraction produced from light passing through patterns, and insufficient transparency of patterns on a photomask result.

Additionally, the off-axis illumination (OAI) technique which can increase depth of focus (DOF) and improve resolution without changing lithography parameters or pattern layouts has become essential in present steppers. Nevertheless, as DOF increases, illumination intensity of the OAI must continuously be enhanced, resulting in a non-uniform received dose (RD) on the photoresist resulting in CD bias between patterns. Thus, in follow-up processes such as alignment of the previous layer, CD bias can result in overlap errors (OE) forming unexpected openings and shorts, adversely affecting the quality of products.

### SUMMARY OF THE INVENTION

In order to solve the problems of the conventional method, an object of the invention is to provide a photomask structure for improving CD uniformity between array patterns and reducing pattern displacement and method thereof.

The photomask structure for improving CD uniformity and reducing pattern displacement provided in the invention consists of a transparent substrate and a light-shielding layer, with the light-shielding layer including an array pattern area and a plurality of assist patterns disposed therein. The distance between the assist pattern and its upper and lower array patterns is equal, and the length of the assist pattern is equal to the width of the array pattern. The transparent substrate is a quartz substrate, and the light-shielding layer is a chromium layer.

Another method of reducing lens aberration and pattern displacement provided in the invention includes the following steps. First, a substrate with a photoresist layer thereon is provided, then the photoresist layer is patterned by a photomask, and an array trench area in the substrate is etched using the patterned photoresist as a mask.

According to the photomask provided in the present invention, assist patterns thereon increase transparency of array patterns and compensate for the degradation of light intensity at the pattern edges by diffraction, thereby improving CD uniformity between array patterns.

In addition, assist patterns also control RD to reduce pattern displacement significantly to facilitate the alignment of underlying layers.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a plane view of a partial layout of the conventional photomask.

FIG. 2 is a plane view of a partial layout of the photomask provided in the present invention.

FIG. 3 is a cross section of FIG. 2.

FIG. 4A is a cross section of the lithography.

FIG. 4B is a cross section of the substrate after etching.

FIG. 5A is a plane view of the CD bias between array patterns using the conventional photomask with 3θ lens aberration after etching.

FIG. 5B is a plane view of the CD bias between array patterns using the photomask provided in the present invention with 3θ lens aberration after etching.

FIG. 6A is a plane view of the CD bias between array patterns using the conventional photomask with coma lens aberration after etching.

FIG. 6B is a plane view of the CD bias between array patterns using the photomask provided in the present invention with coma lens aberration after etching.

### DETAILED DESCRIPTION OF THE INVENTION

FIGS. 2˜6B illustrate the method of reducing lens aberration and pattern displacement according to the invention.

First, referring FIG. 3, a photomask substrate 10 comprising a transparent substrate 103 and a light-shielding layer 104 is provided, wherein the transparent substrate 103 is quartz, and the light-shielding layer 104 is a chromium layer.

Then, referring to FIG. 2, patterns (102 and 106) are transferred to the photomask substrate 10 by writing directly with an electric beam to form an array pattern area 102 and assist patterns 106 thereon. The area, inclusive of the above patterns, is the light-shielding area 104. In the embodiment described herein, array patterns are array trench patterns. However, the invention is not limited to the disclosed embodiment. To the contrary, it is intended to cover various array patterns. The distance between the assist pattern and its upper and lower array patterns is equal. The width of the assist pattern is about 60-80 nm, preferably about 70 nm, thereby no extra patterns are formed on the photoresist after exposure. The length of the assist pattern is equal to the width of the array pattern.

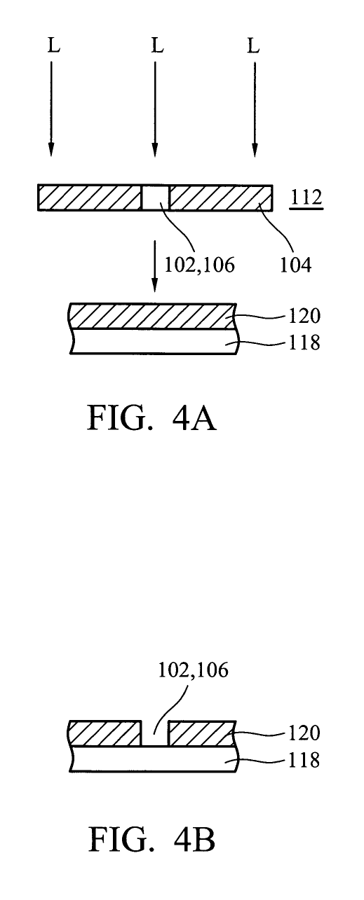

Lithography is shown in FIG. 4A. First, the light L produced from light generator (not shown) passes through patterns (102 and 106) on the photomask 112 to focus on the photoresist 120 on the wafer 118. Next, the developing is performed using the patterned photoresist 120 as a mask to form a pattern area (102 and 106) in the photoresist 120 on the wafer 118, as shown in FIG. 4B. Then, the conventional wet etching or dry etching is conducted to form array trenches in the substrate.

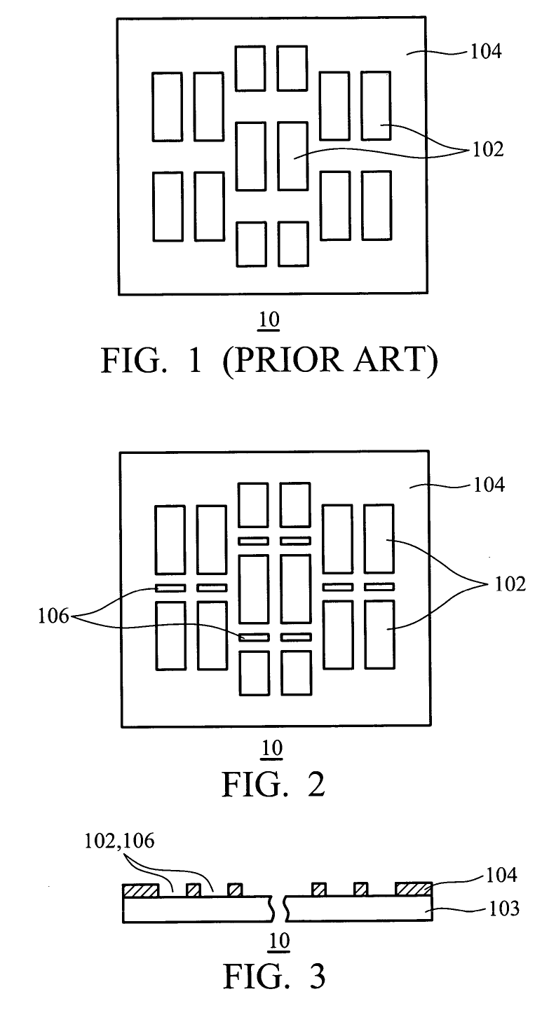

The array pattern area of the photomask provided in the present invention (as shown in FIG. 2), has higher transparency than the conventional photomask (as shown in FIG. 1) due to the assist patterns provided thereon. After etching, CD uniformity between array patterns in the present invention is better than in the conventional method. A detailed description is given in the following experimental data and accompanying drawings.

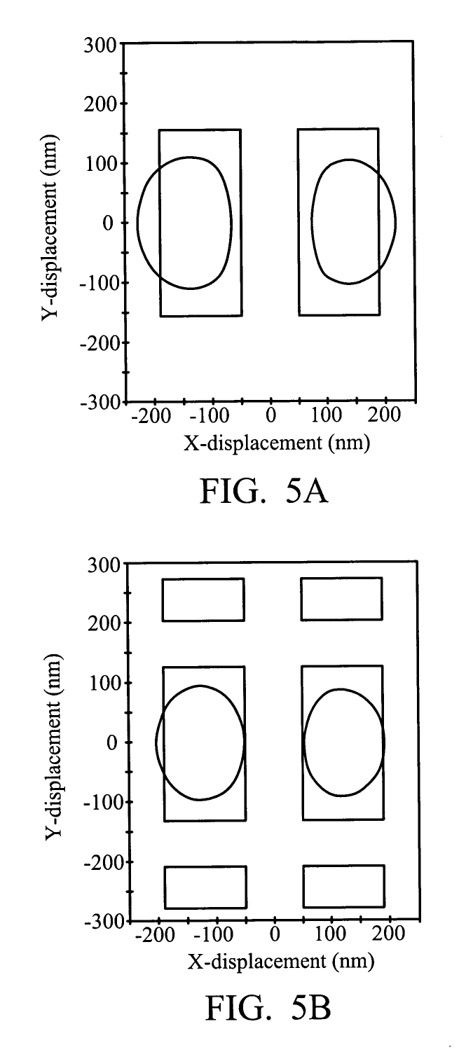

Among the aforementioned types of lens aberration, distortion and coma lens aberration are significant effects in the experiment, particularly the 3θ lens aberration. The experiment is conducted to obtain two groups of data as described in the following. The first group of data is obtained with the 3θ lens aberration, and a detailed description is given with reference to FIGS. 5A and 5B. After etching, using the conventional photomask, the CD bias between trenches is 18.2 nm, for example, the left trench is 138.2 nm, and the right trench is 120.0 nm, as shown in FIG. 5A. The CD bias between trenches is 8.3 nm using the photomask provided in the present invention, for example, the left trench is 140.5 nm and the right trench is 132.2 nm, as shown in FIG. 5B. Accordingly, the effect of the 3θ lens aberration can be reduced by the photomask provided in the present invention to 40%-60%.

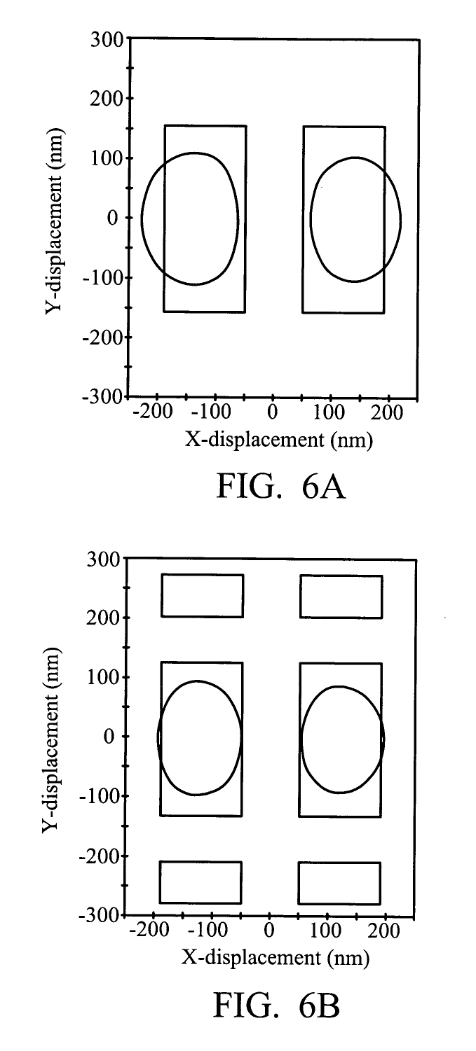

The second group data is obtained with the coma lens aberration, and a detailed description is given in referring to FIGS. 6A and 6B. After etching, using the conventional photomask, the CD bias between trenches is 11.6 nm, for example, the left trench is 134.2 nm, and the right trench is 145.8 nm, as shown in FIG. 6A. The CD bias between trenches is 6.6 nm using the photomask provided in the present invention, for example, the left trench is 134.5 nm and the right trench is 141.1 nm, as shown in FIG. 6B. Accordingly, the effect of the coma lens aberration can be reduced by the photomask provided in the present invention to about 30%˜50%.

In addition, pattern displacement resulting from OAI is improved significantly by the photomask provided in the present invention. A detailed description is given in the following data. After etching, using the conventional photomask, compared to the original location of the left trench, the deviation distance thereof is about 10 nm. The deviation distance of the right trench is also about 10 nm. The deviation distance of the left trench, compared to the original location thereof, is about 2.5 nm, and the right trench is about 2.5 nm using the photomask provided in the present invention. Accordingly, pattern displacement can be reduced by the photomask provided in the present invention to about 75%.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A photomask structure for reducing lens aberration and pattern displacement, comprising:
a transparent substrate; and
a light-shielding layer, disposed on the transparent substrate and having an array pattern area and a plurality of assist patterns, wherein the distance between the assist pattern and its upper and lower array patterns is equal and the length of the assist pattern is equal to the width of the array pattern.

2. The method as claimed in claim 1, wherein the transparent substrate is a quartz substrate.

3. The method as claimed in claim 1, wherein the transparent substrate is a calcium fluoride substrate.

4. The method as claimed in claim 1, wherein the light-shielding layer is chromium.

5. The method as claimed in claim 1, wherein the thickness of the light-shielding layer is about 150˜200 nm.

6. The method as claimed in claim 1, wherein the width of the assist pattern is about 60-80 nm.

7. A method of reducing lens aberration and pattern displacement, comprising:
providing a substrate with a photoresist layer thereon;
defining the photoresist layer by a photomask, wherein the photomask has an array pattern area and a plurality of assist patterns and the distance between the assist pattern and its upper and lower array patterns is equal, further the length of the assist pattern is equal to the width of the array pattern; and
etching an array trench area in the substrate using the patterned photoresist layer as a mask.

8. The method as claimed in claim 7, wherein the substrate is a silicon substrate.

9. The method as claimed in claim 7, wherein the width of the assist pattern is about 60˜80 nm.

10. The method as claimed in claim 7, wherein no additional patterns are formed in the photoresist layer after the pattern is defined.

11. The method as claimed in claim 7, after etching, reducing the CD bias between array patterns to 40%˜60%.

12 The method as claimed in claim 7, after etching, reducing pattern displacement to 40%˜80.
